(19) United States
(12) Patent Application Publication
(10) Pub. No.: US 2025/0353865 A1
(43) Pub. Date: Nov. 20, 2025

(54) AMINE ADDUCTS OF GROUP 2 METALLOCENE PRECURSORS FOR DEPOSITON OF GROUP 2 METAL FILMS

(71) Applicant: Ereztech LLC, Johns Creek, GA (US)

(72) Inventors: Hima Kumar Lingam, Germantown, WI (US); Anuththara Chalani Upeksha Abesinghe Arachchige, Sheboygan Falls, WI (US); David Allen Roberts, Fogelsville, PA (US)

(21) Appl. No.: 19/210,360

(22) Filed: May 16, 2025

Related U.S. Application Data
(60) Provisional application No. 63/648,415, filed on May 16, 2024.

(51) Int. Cl. C07F 3/02; C23C 16/455

(52) U.S. Cl. CPC C07F 3/02; C23C 16/45553

(57) ABSTRACT

This invention is related to Group 2 metal-containing organometallic precursors of Formula (I) and (II). The compounds and compositions are useful for fabricating metal containing films on substrates such as silicon, metal nitride, metal oxide and other metal layers via chemical vapor deposition (CVD) processes.

### TECHNICAL FIELD

The field of the disclosure relates generally to semiconductor industry and, more specifically, compounds and methods of Group 2 organometallic precursors for fabricating metal containing films on substrates via chemical vapor deposition processes.

### BACKGROUND OF THE INVENTION

The present invention relates to precursors for use in depositing Group 2 metal-containing films on substrates such as, for example, Si, SiC, GaN, and Al₂O₃ wafers or other microelectronic device substrates, as well as associated processes of making thin film coatings for non-electronic device applications such as, for example, optical, protective, hermetically sealing, and numerous other non-electronic applications.

In the semiconductor industry there is a growing need for volatile sources of different metal precursors to be deposited on substrates by deposition techniques such as chemical vapor deposition (CVD) and atomic layer deposition (ALD). Such deposition requires monomeric metal precursors that are transportable (volatile) at temperatures specific to the deposition process.

Along with being one of the world's most used metals, magnesium, for example, also has the best strength-to-weight ratio. Lightweight yet incredibly strong, it's the ideal material for electronics. Magnesium has better thermal conductivity properties than plastic, which also makes it a better choice in electronic appliances to dissipate heat generated by electronic circuits. Magnesium alloys are used in laptops, TVs, LCDs and PC casings. It's estimated that magnesium laptop parts are also 20 times stronger than typical thermoplastic.

Magnesium oxide and other Group 2 metal oxides are used for thin film coating applications. MgO, for example, has a high dielectric constant and low leakage current, making it an ideal material for implementing gate dielectrics in thin film transistors (TFTs). The MgO layer is used as a buffer layer between the semiconductor layer and the gate electrode, which can improve the electrical performance and stability of the TFT by reducing leakage current and increasing carrier mobility. Apart from it, the layer is very stable, and it helps to extend the lifetime of the TFT.

Specifically, magnesium oxide (MgO) is a semiconductor with a wide band-gap and electrical insulating properties. A very thin insulating MgO layer between two metallic ferromagnetic layers is used as a “magnetic tunnel junction.” Magnetic tunneling junctions (MTJs) based on, for example, the CoFeB/MgO/CoFeB layer have received great attention as a promising candidate for future spin logic devices. Among various applications of MTJs, spin-transfer-torque magnetic random access memory (STT-MRAM) is emerging as a strong candidate as a next-generation nonvolatile memory due to its simple integration scheme, low voltage operation, and high speed. To fulfill certain critical requirements of 3D MTJ based sub-20 nm, high-density STT-MRAM, Samsung Advanced Institute of Technology (SAIT), Korea, has recently investigated both thermal and plasma-enhanced ALD for depositing a MgO tunnel barrier using bis(cyclopentadienyl)magnesium precursor under the scope of the Industrial Strategic Technology Development Program (10041926, Development of high-density plasma technologies for the thin-film deposition of nanoscale semiconductors and flexible-display processing) funded by the Ministry of Knowledge Economy (MKE, Korea) (Journal of Alloys and Compounds, Volume 588, 5 Mar. 2014, Pages 716-719).

Recently, Panasonic Corporation, Japan, together with the National Institute of Material Science, Japan, reported ALD based Magnesium Phosphate (MgPO) thin-films as magnesium-ion conducting solid-state electrolytes that are considered to be promising candidates for future energy storage and conversion devices. The deposition was carried out at lower deposition temperatures, ranging from 125 to 300° C., using bis(ethylcyclopentadienyl)magnesium (Chem. Mater. 2019, 31, 15, 5566-5575).

Apart from semiconductor and energy storage applications, Mg is also an interesting candidate for astronomical and optical applications. For example, recent NASA missions that make observations in the ultraviolet, such as the Hubble Space Telescope and the Galaxy Evolution Explorer, employed primary mirrors coated with aluminum and further protected by thin films of Magnesium Fluoride (MgF₂). Therefore, the Jet Propulsion Laboratory, California Institute of Technology, under a contract with NASA, reported ALD of MgF₂ using bis(ethylcyclopentadienyl)magnesium (J. Vac. Sci. Technol. A 33, 01A125 (2015)).

Magnesium-doped semiconductors have existing and anticipated applications in the fabrication of blue and green light-emitting diodes, blue and green laser diodes, and in microelectronics devices. Magnesium volatile precursors for thin film applications often feature two cyclopentadienyl ligands, i.e., magnoscene, or one of variously substituted cyclopentadienyl variations. At present, the area is limited by the precursor characteristics of the bis(cyclopentadienyl)magnesium and substituted derivatives.

It is advantageous in many applications for Group 2 organometallic precursors to be in liquid form at the delivery temperature used in the deposition process. Liquids are more readily transferred from their containment vessel to a vaporizer, for example.

In applications where the precursor vapor is transported from bulk precursor in the containment vessel to the surface of the deposition substrate, either by a sweep gas or vacuum draw, liquids typically are preferred for maintaining more uniform mass transfer versus solid sources (see, e.g., Vahlas, C., et al., Liquid and solid precursor delivery systems in gas phase processes, Recent Patents on Materials Science, 2015.8 (2): p. 91-108). For example, the precursors should have melting points below the operating temperature of the vaporizer that is used in a liquid delivery deposition process system, to avoid clogging of the vaporizer and to minimize the potential for particle generation by the vaporizer. Such clogging and particle generation issues are particularly common when solutions of solid precursors are used in deposition.

A problem associated with the magnocenes noted above and similar complexes with other group 2 alkaline earth metal precursors, however, is that they are pyrophoric and require special safety procedures to handle them both prior to and during use. For example, the compound di(tert-butylcyclopentadienel)magnesium is reported as being highly sensitive to air and moisture and any handling of the compound occurred under an argon atmosphere and using ketylated solvents (see Thiele and Lorenz, “Synthesis and Properties of Di(tert-butylcyclopentadienel)magnesium (With Comments on Di(methylcyclopentadienel)magnesium)), Technical University “Carl Schorlemmer”, Chemistry Section, Z. Anorg. All. Chem. 591 (1990) 195-198). It would therefore be a substantial advance in the art to provide Group 2 organometallic precursors having low melting point, e.g., below 80° C., to support handling of the complex as a liquid and additionally minimize and preferably avoid the aforementioned pyrophoric risk.

Accordingly, the semiconductor fabrication industry continues to demand novel Group 2 metal sources containing precursors for vapor deposition processes for fabricating conformal Group 2 metal-containing films on substrates that are sufficiently volatile and are safer to store, transfer, and use.

### BRIEF SUMMARY OF THE INVENTION

In one aspect, the present invention provides a composition comprising an organometallic complex of Formula I:

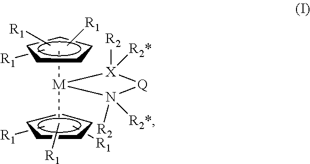

wherein,
M is selected from the group consisting of Mg, Ca, Ba, and Sr;
X is selected from the group consisting of N and O, provided that when X is O, the R₂* is absent;
Q is either the ligand

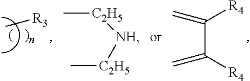

provided that when Q is

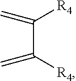

each R₂* is not present;
each R₁ is independently hydrogen or a C₁-C₄ linear or branched alkyl;
each R₂ and R₂* is independently selected from the group consisting of hydrogen, methyl, ethyl, n-propyl, iso-propyl, n-butyl, iso-butyl, and tert-butyl, wherein at least one R₁ may be connected to an R₂ to form a C₂-C₅ alkylene bridge; R₃ is selected from the group consisting of hydrogen or a C₁-C₄ linear or branched alkyl;
each R₄ is independently hydrogen or a C₁-C₄ linear or branched alkyl; and
n is 0, 2, 3, 4 or 5,
wherein when Q is

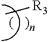

and n is 0, then at least one N forms a C₂-C₅ alkylene bridge with an R₁ via either R₂ or R₂*, and the other N either forms a C₂-C₅ alkylene bridge with
another R₁ via either R₂ or R₂*, or is

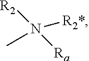

wherein Rₐ is a C₁-C₄ linear or branched alkyl, and provided that, when n is 2, not all of R₁ and R₂ are methyl or hydrogen when R₃ is hydrogen.

In another aspect, the present invention provides a method of forming a layer on a substrate, such as is used in the manufacturing of a semiconductor structure. The method includes the steps of providing a substrate; providing a vapor including one or more Group 2 metal precursor compounds of Formula (I); and forming a metal-containing layer on a surface of the substrate using an atomic layer deposition process that includes a plurality of deposition cycles.

In yet another aspect, the present invention provides a method of forming a layer on a substrate. The method includes the steps of providing a substrate; providing a vapor including one or more Group 2 metal precursor compounds of Formula (I); providing one or more reaction gases; and directing the vapor including the one or more Group 2 metal precursor compounds and the one or more reaction gases to the substrate to form a metal-containing layer on a surface of the substrate using a chemical vapor deposition process.

The various aspects and embodiments of the invention can be used alone or in combination with each other.

### BRIEF DESCRIPTION OF SEVERAL VIEWS OF THE DRAWINGS

FIG. 1 is a crystal structure of N1,N1,N3,N3-Tetramethyl-1,3-butanediamine from the Examples; and

FIG. 2 shows the TGA curves for compounds of the Examples.

FIG. 3 shows 1H NMR spectrum of Ba(ipr3Cp)₂ (TEEDA).

FIG. 4 shows 1H NMR spectrum of Ba(ipr3Cp)₂ (Me₂NCH₂CH₂CH₂NMe₂).

### DETAILED DESCRIPTION OF THE INVENTION

### Definitions

Unless defined otherwise, all technical and scientific terms have the same meaning as is commonly understood by one of ordinary skill in the art to which the disclosed embodiments belong.

As used herein, the terms “a” or “an” mean “at least one” or “one or more” unless the context clearly indicates otherwise.

As used herein, the term “about” means that the recited numerical value is approximate and small variations would not significantly affect the practice of the disclosed embodiments. Where a numerical value is used, unless indicated otherwise by the context, “about” means the numerical value can vary by +10% and remain within the scope of the disclosed embodiments.

As used herein, the terms “comprising” (and any form of comprising, such as “comprise”, “comprises”, and “comprised”), “having” (and any form of having, such as “have” and “has”), “including” (and any form of including, such as “includes” and “include”), or “containing” (and any form of containing, such as “contains” and “contain”), are inclusive and open-ended and include the options following the terms, and do not exclude additional, unrecited elements or method steps.

“Substrate” as used herein refers to any base material or construction upon which a metal-containing layer can be deposited. The term “substrate” is meant to include semiconductor substrates and also include non-semiconductor substrates such as films, molded articles, fibers, wires, glass, ceramics, machined metal parts, etc.

“Semiconductor substrate” or “substrate assembly” as used herein refers to a semiconductor substrate such as a metal electrode, base semiconductor layer or a semiconductor substrate having one or more layers, structures, or regions formed thereon. A base semiconductor layer is typically the lowest layer of silicon material on a wafer or a silicon layer deposited on another material, such as silicon on sapphire. When reference is made to a substrate assembly, various process steps may have been previously used to form or define regions, junctions, various structures or features, and openings such as capacitor plates or barriers for capacitors.

“Layer” as used herein refers to any metal-containing layer that can be formed on a substrate from the precursor compounds of this invention using a vapor deposition process. The term “layer” is meant to include layers specific to the semiconductor industry, such as “barrier layer,” “dielectric layer,” and “conductive layer.” (The term “layer” is synonymous with the term “film” frequently used in the semiconductor industry.) The term “layer” is also meant to include layers found in technology outside of semiconductor technology, such as coatings on glass.

“Dielectric layer” as used herein is a term used in the semiconductor industry that refers to an insulating layer (sometimes referred to as a “film”). For this invention, the dielectric layer contains a Group 2 metal compound, examples including barium titanate, strontium titanate, barium-strontium titanate, calcium titanate and magnesium titanate.

“Precursor compound” as used herein refers to a Group 2 metal compound capable of forming (typically in the presence of a reaction gas) a metal-containing layer on a substrate in a vapor deposition process. Examples of commonly deposited Group 2 metal-containing layers include oxide, sulfide, fluoride and various other combinations of Group 2 metals and Group V, VI and VII elements, resulting in a rich array of materials useful for their electrical, mechanical and barrier properties.

“Deposition process” and “vapor deposition process” as used herein refer to a process in which a metal-containing layer is formed on one or more surfaces of a substrate (e.g., a doped polysilicon wafer) from vaporized precursor compound(s). Specifically, one or more metal precursor compounds are vaporized and directed to one or more surfaces of a heated substrate (e.g., semiconductor substrate or substrate assembly) placed in a deposition chamber. These precursor compounds form (e.g., by reacting or decomposing) a non-volatile, thin, uniform, metal-containing layer on the surface(s) of the substrate. For the purposes of this invention, the term “vapor deposition process” is meant to include both chemical vapor deposition processes (including pulsed chemical vapor deposition processes) and atomic layer deposition processes. There are several overviews of the vapor deposition processes in the chemical literature, see for example: Jones, A. C. and M. L. Hitchman, Overview of chemical vapour deposition. Chemical vapour deposition: precursors, processes and applications, 2009. 1: p. 1-36.

“Chemical vapor deposition” (CVD) as used herein refers to a vapor deposition process wherein the desired layer is deposited on the substrate from vaporized metal precursor compounds and any reaction gases used within a deposition chamber with no effort made to separate the reaction components. In contrast to a “simple” CVD process that involves the substantial simultaneous use of the precursor compounds and any reaction gases, “pulsed” CVD alternately pulses these materials into the deposition chamber, but does not rigorously avoid intermixing of the precursor and reaction gas streams, as is typically done in atomic layer deposition or ALD (discussed in greater detail below). Also, for pulsed CVD, the deposition thickness is dependent on the exposure time, as opposed to ALD, which is self-limiting (discussed in greater detail below).

“Atomic layer deposition” (ALD) as used herein refers to a vapor deposition process in which numerous consecutive deposition cycles are conducted in a deposition chamber. Typically, during each cycle the metal precursor is chemisorbed to the substrate surface; excess precursor is purged out; a subsequent precursor and/or reaction gas is introduced to react with the chemisorbed layer; and excess reaction gas (if used) and by-products are removed. As compared to the one cycle chemical vapor deposition (CVD) process, the longer duration multi-cycle ALD process allows for improved control of layer thickness by self-limiting layer growth and minimizing detrimental gas phase reactions by separation of the reaction components.

“Chemisorption” as used herein refers to the chemical adsorption of vaporized reactive precursor compounds on the surface of a substrate.

In the formulae herein and through the description, the term “C₁-C₄ alkyl” denotes a group derived from an alkane by removal of one hydrogen atom and having from 1 to 4 carbon atoms. Exemplary linear C₁-C₄ alkyl groups include, but are not limited to, methyl, ethyl, n-propyl, and n-butyl. Exemplary branched C₁-C₄ alkyl groups include, but are not limited to, iso-propyl, tert-butyl, and sec-butyl.

In the formulae herein and throughout the description, the term “cyclic alkyl” denotes a cyclic functional group having from 3 to 10 or from 4 to 10 carbon atoms or from 5 to 10 carbon atoms. Exemplary cyclic alkyl groups include, but are not limited to, cyclobutyl, cyclopentyl, cyclohexyl, and cyclooctyl groups.

As used herein, the term “alkylene” or “alkylenyl” means a divalent alkyl linking group. Example of alkylenes (or alkylenyls) include, but are not limited to, methylene or methylenyl (—CH₂—), ethylene or ethylenyl (—CH₂—CH₂—), and propylene or propylenyl (—CH₂—CH₂—CH₂—).

### Compounds

This invention is related to Group 2 metal containing organometallic precursors and compositions comprising Group 2 metal containing organometallic precursors as well as methods to form films using Group 2 metal containing organometallic precursors and compositions disclosed herein. The compounds and compositions are useful for fabricating Group 2 metal containing films on substrates such as silicon, metal nitride, metal oxide and other metal layers via chemical vapor deposition processes. As used herein, the term “chemical vapor deposition processes” refers to any process wherein a substrate is exposed to one or more volatile precursors, which react and/or decompose on the substrate surface to produce the desired deposition. Examples include plasma enhanced chemical vapor deposition (PECVD), low pressure chemical vapor deposition (LPCVD), direct liquid injection chemical vapor deposition (DLCVD), hot wire chemical vapor deposition (HWCVD), cyclic chemical vapor deposition (CCVD), molecular layer deposition (MLD), atomic layer deposition (ALD), and metal-organic chemical vapor deposition (MOCVD). The deposited metal films (which includes Group 2 metal oxide films) have applications ranging from computer chips, optical device, magnetic information storage, to metallic catalyst coated on a supporting material.

The organometallic compounds of the present invention are amine adduct derivatives of Group 2 metallocenes having the general formula Cp-M-Cp, where Cp is a cyclopentadienyl moiety. Organometallic compounds of the present invention are represented by the structure of Formula I:

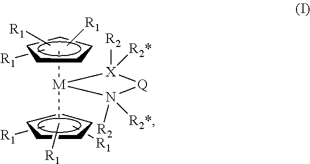

wherein,
M is selected from the group consisting of Mg, Ca, Ba, and Sr;
X is selected from the group consisting of N and O, provided that when X is O, the R₂* is absent;
Q is either the ligand

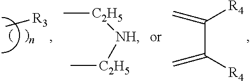

provided that when Q is

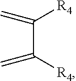

each R₂* is not present;
each R₁ is independently hydrogen or a C₁-C₄ linear or branched alkyl;
each R₂ and R₂* is independently selected from the group consisting of hydrogen, methyl, ethyl, n-propyl, iso-propyl, n-butyl, iso-butyl, and tert-butyl, wherein at least one R₁ may be connected to an R₂ to form a C₂-C₅ alkylene bridge;
R₃ is selected from the group consisting of hydrogen or a C₁-C₄ linear or branched alkyl;
each R₄ is independently hydrogen or a C₁-C₄ linear or branched alkyl; and
n is 0, 2, 3, 4 or 5,
wherein when Q is

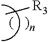

and n is 0, then at least one N forms a C₂-C₅ alkylene bridge with an R₁ via either R₂ or R₂*, and the other N either forms a C₂-C₅ alkylene bridge with
another R₁ via either R₂ or R₂*, or is

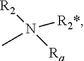

wherein Rₐ is a C₁-C₄ linear or branched alkyl, and provided that, when n is 2, not all of R₁ and R₂ are methyl or hydrogen when R₃ is hydrogen.

Preferably, the compounds of Formula I are monomers under the conditions of vapor being transported to the substrate surface for reaction. Without intending to be bound by a particular theory, It is believed that, in solution, the molecules could exist as an equilibrium mixture of a monomer and a dimer, or other aggregate, but at elevated temperatures the compounds vaporize as the monomeric form. Preferably, the compounds of Formula I also have a melting point in the range of from 10 to 80° C. Monomeric metallic precursors are more readily transportable (i.e., more volatile) at temperatures specific to CVD and ALD processes, inclusive of plasma enhanced CVD and ALD processes. Techniques suitable for determining whether the compounds according to Formula (I) are monomeric include methods known to the skilled artisan such as, for example, ¹H NMR and X-ray diffraction crystallography.

In embodiments, M is a Group 2 metal of the Periodic Table of Elements. The Group 2 metals include beryllium (Be), magnesium (Mg), calcium (Ca), strontium (Sr), barium (Ba) and radium (Ra). In other embodiments, M is selected from the group consisting of Mg, Ca, Ba, and Sr. In certain embodiments, M is selected from the group consisting of Mg, Ba, and Sr. In yet other embodiments, M is Mg.

In some embodiments, the M in the M-Cp complexes of Formula (I) is bound to all 5 carbons of the Cp. In other embodiments, the M in the M-Cp complexes of Formula (I) is bound to only one carbon in each of the Cp rings. Accordingly, the structures shown herein are inclusive of any number of bonds between the metal and the Cp rings, which may also vary between the two Cp rings on the same metal.

In Formula (I) above, each R₁ is independently hydrogen or a C₁-C₄ linear or branched alkyl; each R₂ and R₂* is independently selected from the group consisting of hydrogen, methyl, ethyl, n-propyl, iso-propyl, n-butyl, tert-butyl, and iso-butyl, wherein at least one R₁ may be connected to an R₂ to form a C₂-C₅ alkylene bridge; R₃ is selected from the group consisting of hydrogen or a C₁-C₄ linear or branched alkyl; and each R₄ is independently hydrogen or a C₁-C₄ linear or branched alkyl.

In certain embodiments of Formula (I), X is N, Q is

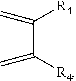

provided that when Q is

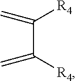

each R₂* is not present to account for a total number of four covalent bonds on each of the nitrogen atoms, wherein one of the valencies on each nitrogen atom is a coordinate (i.e., a dative) covalent bond in which both electrons come from the same atom. For example, a pair of electrons associated with the nitrogen may be shared with an empty orbital on the metal to form a dative covalent bond. When Q is

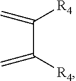

the general structure of Formula (1) becomes Formula (I*)

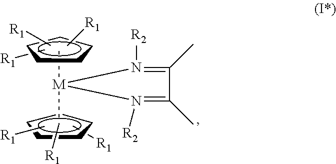

wherein R₁ and R₂ are defined as above. An example of a compound of Formula (I*) is the following compound (I*a), wherein one R₁ is H and each of the other R₁ is a methyl group on each Cp and each R₂ is an ethyl group:

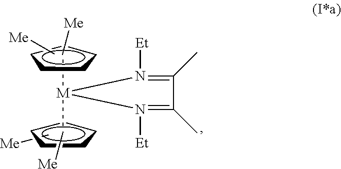

wherein M is Mg. In other embodiments of Formula (I*), each R₁ and each R₂ are selected from the group consisting of an ethyl group and an iso-propyl group; and M is selected from the group consisting of Mg, Ca, Sr, and Ba.

In some embodiments of Formula (I), Q is

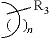

and n is not 0. In such embodiments, n is 2, 3, 4 or 5. An example of an organometallic compound of Formula (I) is wherein X is N, Q is

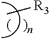

and n is 2, each R₁ is H, each R₂ and R₂* is methyl, and R₃ is H is compound (I-a):

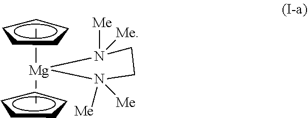

Another example of an organometallic compound of Formula (I) wherein X is N, Q is

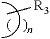

and n is 2, one R₁ is methyl and each of the other R₁ is H on each Cp, each R₂ and R₂* is ethyl, and R₃ is ethyl is compound (I-b):

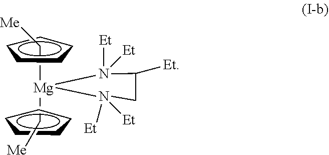

Yet another example of an organometallic compound of Formula (I) wherein X is N, Q is

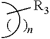

and n is 2, one R₁ is H and each of the other R₁ is iso-propyl on each Cp, each R₂ and R₂* is ethyl, and R₃ is H is compound (I-c):

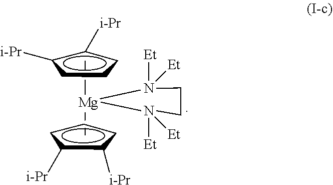

Yet another example of an organometallic compound of Formula (I) wherein X is N, Q is

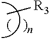

and n is 2, one R₁ is methyl and each of the other R₁ is H on each Cp, each of R₂ and R₂* is ethyl on each nitrogen, and R₃ is H is compound (I-d):

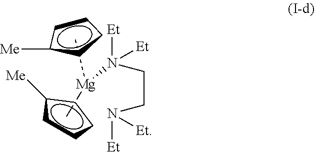

Yet another example of an organometallic compound of Formula (I) wherein X is N, Q is

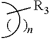

and n is 2, one R₁ is methyl and each of the other R₁ is H on each Cp, one of R₂ and R₂* is ethyl on each nitrogen, and R₃ is H is compound (I-e):

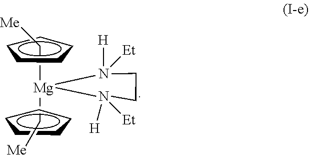

An example of an organometallic compound of Formula (I) is wherein X is N, Q is

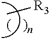

and n is 3, one R₁ is methyl, each of the other R₁ is H on each Cp, each R₂ and R₂* is ethyl, and R₃ is methyl is compound (I-f):

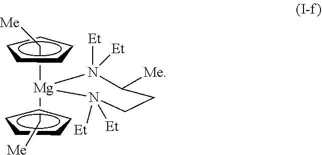

Another example of an organometallic compound of Formula (I) is wherein X is N, Q is

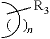

and n is 3, one R₁ is methyl, each of the other R₁ is H on each Cp, each R₂ and R₂* is methyl, and R₃ is H is compound (I-g):

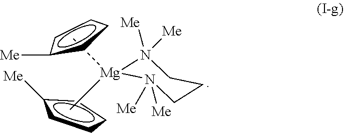

Yet another example of an organometallic compound of Formula (I) is wherein X is N, Q is

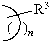

and n is 3, one R₁ is methyl, each of the other R₁ is H on each Cp, each R₂ and R₂* is methyl, and R₃ is methyl is compound (I-h):

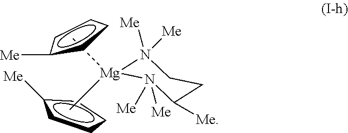

Yet another example of an organometallic compound of Formula (I) is wherein X is N, Q is

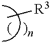

and n is 3, one R₁ is methyl and each of the other R₁ is H on each Cp, each R₂ and R₂* is ethyl, and R₃ is H is compound (I-i):

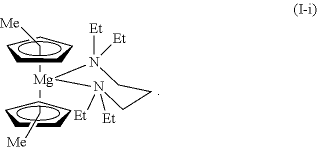

An example of an organometallic compound of Formula (I) is wherein X is N, Q is

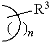

and n is 5, each R₁ is H, each R₂ and R₂* is methyl, and R₃ is H is compound (I-j):

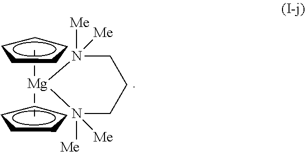

In some embodiments of Formula (I), X is N, Q is

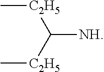

An example of an organometallic compound of Formula (I) is wherein Q is

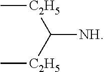

one R₁ on each Cp is methyl and each of the other R₁ on each Cp is H, and each R₂ and R₂* is methyl is compound (I-k):

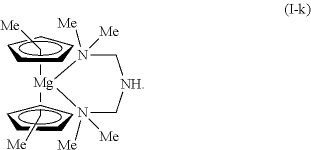

In other embodiments of Formula (I), X is N, Q is

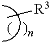

and n is 0, then at least one N forms a C₂-C₅ alkylene bridge with an R₁ via either R₂ or R₂*, and the other N either forms a C₂-C₅ alkylene bridge with another R₁ via either R₂ or R₂*, or is

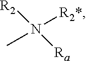

wherein Rₐ is a C₁-C₄ linear or branched alkyl. An example of an organometallic compound of Formula (I) wherein X is N, Q is

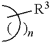

and n is 0, one R₁ on each Cp is methylene and each of the other R₁ on each Cp is H, each R₂ and R₂* is ethyl, and both Nitrogens form an ethylene bridge with the methyl group on each Cp is compound (I-m):

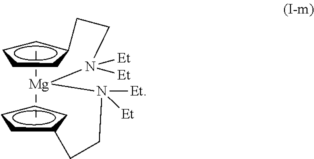

An example of an organometallic compound of Formula (I) wherein X is N, Q is

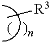

and n is 0, one R₁ on each Cp is methyl and each of the other R₁ on each Cp is H, each of R₂ and R₂* is ethyl, Ra is ethyl, and one of the nitrogens forms an ethylene bridge with the methyl group on a Cp is compound (I-n):

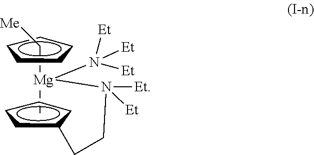

In some embodiments of Formula (I), M is Ba. An example of an organometallic compound of Formula (I) is wherein X is N, Q is

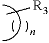

and n is 2, each R₁ is an iso-propyl group, each R₂ and R₂* is an ethyl group, and R₃ is H is compound (I-o):

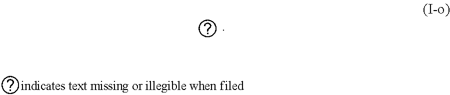

Yet another example of an organometallic compound of Formula (I) is wherein X is N, Q is

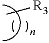

and n is 3, each R₁ is iso-propyl, each R₂ and R₂* is methyl, and R₃ is H is compound (I-p):

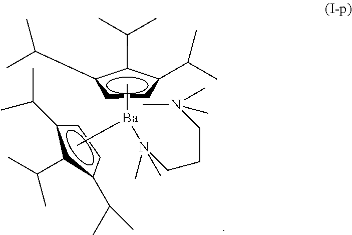

Yet another example of an organometallic compound of Formula (I) is wherein X is N, Q is

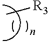

and n is 2, each R₁ is iso-propyl, each R₂ and R₂* is methyl, and R₃ is H is compound (I-q):

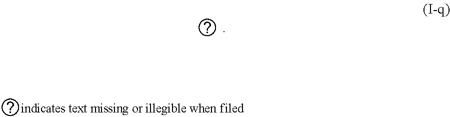

Yet another example of an organometallic compound of Formula (I) is wherein X is N, Q is

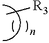

and n is 3, each R₁ is iso-propyl, each R₂ and R₂* is ethyl, and R₃ is H is compound (I-r):

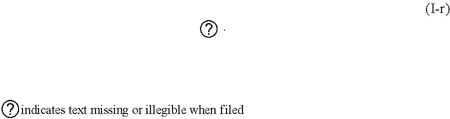

In some embodiments of Formula (I), M is Mg. An example of an organometallic compound of Formula (I) is wherein X is O, Q is

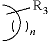

and n is 2, one R₁ on each Cp is methyl and each of the other R₁ on each Cp is H, one of R₂ is methyl and one of R₂* is not present on oxygen, each R₂ and R₂* is ethyl on nitrogen, and R₃ is H is compound (I-s):

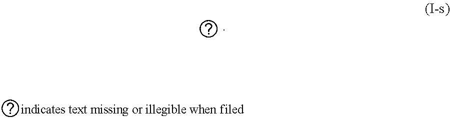

Excluded from the compounds represented by Formula (I) are compounds wherein when n is 2, not all of R₁ and R₂ are methyl or hydrogen when R₃ is hydrogen. For example, the following compound is in the prior art and has a melting temperature that is 126° C., which is higher than is preferred.

In another embodiment, organometallic compounds of the present invention are represented by the structure of Formula II:

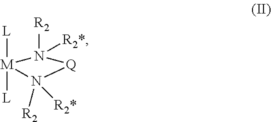

wherein,
M is selected from the group consisting of Mg, Ca, Ba, and Sr;
L is selected from the group consisting of

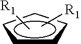

and a C₁-C₆ linear or branched alkyl;
Q is either the ligand

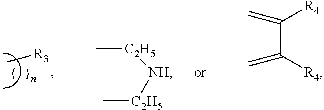

provided that when Q is

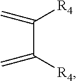

each R₂* is not present;
each R₁ is independently hydrogen or a C₁-C₄ linear or branched alkyl;
each R₂ and R₂* is independently selected from the group consisting of hydrogen, methyl, ethyl, n-propyl, iso-propyl, n-butyl, tert-butyl, and iso-butyl, wherein at least one R₁ may be connected to an R₂ to form a C₂-C₅ alkylene bridge;
R₃ is selected from the group consisting of hydrogen or a C₁-C₄ linear or branched alkyl;
each R₄ is independently hydrogen or a C₁-C₄ linear or branched alkyl; and
n is 0, 2, 3, 4 or 5,
wherein when Q is

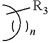

and n is 0, then at least one N forms a C₂-C₅ alkylene bridge with an R₁ via either R₂ or R₂*, and the other N either forms a C₂-C₅ alkylene bridge with another R₁ via either R₂ or R₂*, or is

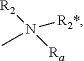

wherein Rₐ is a C₁-C₄ linear or branched alkyl, and provided that, when n is 2, not all of R₁ and R₂ are methyl or hydrogen when R₃ is hydrogen.

Examples of organometallic precursor compounds of Formula (II) include

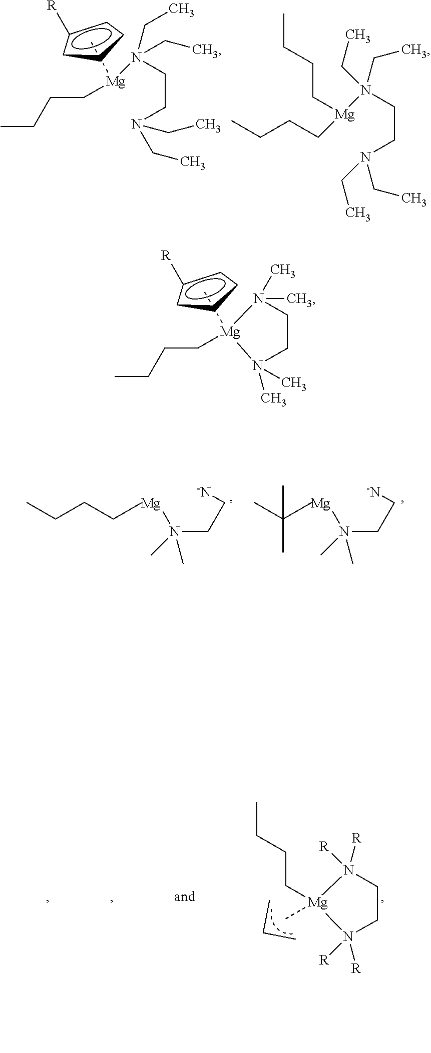

### R=Me and Et.

The compounds of Formula (I) and (II) have low melting points (<80° C.), good transport and deposition properties for forming conformal films on substrates, and good handling characteristics and stability with respect to oxygen and moisture.

The organometallic precursors of Formula (I) and (II) can be supplied in any suitable form for volatilization to produce the precursor vapor for deposition contacting with the substrate, e.g., in a liquid form that is vaporized or as a solid that is dissolved or suspended in a solvent medium for flash vaporization, as a sublimable solid, or as a solid having sufficient vapor pressure to render it suitable for vapor delivery to the deposition chamber, or in any other suitable form.

When solvents are employed for delivery of the precursors of the invention, a suitable organic solvent medium can be employed in which the precursor can be dissolved or dispersed for delivery. By way of example, the organic solvent medium may be, for example, an organic solvent selected from the group consisting of an aliphatic ether, a cyclic ether, an aromatic hydrocarbon, an aliphatic hydrocarbon, an alkyl silane, and mixtures thereof. Such solvents are well known to those skilled in the art and may include species such as, for example, C₃-C₁₂ alkanes, C₂-C₁₂ ethers, C₆-C₁₂ aromatics, C₇-C₁₆ arylalkanes, C₁₀-C₂₅ arylcyloalkanes, and further alkyl-substituted forms of aromatic, arylalkane and arylcyloalkane species.

In various embodiments of the present invention, it may be desirable to utilize aromatic solvents such as xylene, 1,4-tertbutyltoluene, 1,3-diisopropylbenzene, tetralin, dimethyltetralin and other alkyl-substituted aromatic solvents.

In other applications, preferred solvents may include amine solvents, neutral amines such as DMAPA, octane or other aliphatic solvents, aromatic solvents such as toluene, ethers such as tetrahydrofuran (THF), and tetraglymes.

Thus, the precursors may be supplied in liquid delivery systems as individual precursors or mixtures of precursors, in solvent media that may be comprised of a single component solvent, or alternatively may be constituted by a solvent mixture, as appropriate in a given application. The solvents that may be employed for such purpose can be of any suitable type in which the specific precursor(s) can be dissolved or suspended, and subsequently volatilized to form the precursor vapor for contacting with the substrate on which the metal is to be deposited.

The invention also contemplates delivery of the precursor by bubbler delivery techniques, in which the bubbler is arranged to operate at or above the melting point of the precursor.

The Group 2 organometallic precursors of the invention can be utilized in combinations, in which two or more of such precursors are mixed with one another, e.g., in a solution as a precursor cocktail composition for liquid delivery.

Alternatively, the precursor species may be individually dissolved in solvent(s) and delivered into vaporizers for volatilization of the precursor solution to form a precursor vapor that then is transported to the deposition chamber of the deposition system to deposit the metal-containing film on a wafer or other microelectronic device substrate.

As a still further alternative, the precursors can be delivered by solid delivery techniques, in which the solid is volatilized to form the precursor vapor that then is transported to the deposition chamber, and with the solid precursor in the first instance being supplied in a packaged form.

The Group 2 organometallic precursors of the present invention are usefully employed for forming metal-containing thin films of high conformality and uniformity characteristics, by ALD and CVD processes. The process conditions for the deposition process in a specific application may be readily determined empirically by variation of specific conditions (temperature, pressure, flow rate, concentration, etc.) and characterization of the resulting film deposit.

As will be described in more detail below, the Group 2 organometallic precursors can be volatilized for the deposition of metal-containing films in any suitable manner and using any suitable vaporizer apparatus or technique. The precursors may be vaporized singly and separately, or they may be volatilized in admixture or solution with one another.

### Methods of Use in Vapor Deposition Processes

The present invention also provides methods of forming a metal-containing layer on a substrate using one or more Group 2 organometallic precursor compounds of Formula (I). Other metal-containing precursor compounds (other than those of Formula I) can also be used as can one or more reaction gases in the methods of the present invention.

In one embodiment, the method comprises the steps of: providing a substrate; providing a vapor including one or more Group 2 metal precursor compounds of Formula (I); and forming a metal-containing layer on a surface of the substrate using an atomic layer deposition process that includes a plurality of deposition cycles.

In another embodiment, the method comprises the steps of providing a substrate; providing a vapor including one or more Group 2 metal precursor compounds of Formula (I); providing one or more reaction gases; and directing the vapor including the one or more Group 2 metal precursor compounds and the one or more reaction gases to the substrate to form a metal-containing layer on a surface of the substrate using a chemical vapor deposition process.

The metal-containing layer formed is a Group 2 metal-containing layer, preferably a magnesium, strontium, and/or barium-containing layer. The layers or films formed can be in the form of Group 2 metal oxide-containing films, for example, wherein the layers include one or more Group 2 metal oxides optionally doped with other metals. Thus, the term “Group 2 metal oxide” films or layers encompass just Group 2 metal oxide as well as doped films or layers (i.e., mixed metal oxides), such as a magnesium titanate, strontium titanate, barium titanate, or a titanate layer comprising a mixture of such metals.

The substrate on which the metal-containing layer is formed is preferably a semiconductor substrate or substrate assembly. Any suitable semiconductor material is contemplated, such as for example, conductively doped polysilicon (for this invention simply referred to as “silicon”). A substrate assembly may also contain a layer that includes platinum, iridium, rhodium, ruthenium, ruthenium oxide, titanium nitride, tantalum nitride, tantalum-silicon-nitride, silicon dioxide, aluminum, gallium arsenide, glass, etc., and other existing or to-be-developed materials used in semiconductor constructions, such as dynamic random access memory (DRAM) devices and ferroelectric memory (FeRAM) devices, for example.

Substrates other than semiconductor substrates or substrate assemblies can be used in methods of the present invention. These include, for example, fibers, wires, etc. If the substrate is a semiconductor substrate or substrate assembly, the layers can be formed directly on the lowest semiconductor surface of the substrate, or they can be formed on any of a variety of the layers (i.e., surfaces) as in a patterned wafer, for example.

As a means of simplifying the discussion and the recitation of certain terminology used throughout this application, the terms “group” and “moiety” are used to differentiate between chemical species that allow for substitution or that may be substituted and those that do not so allow for substitution or may not be so substituted. Thus, when the term “group” is used to describe a chemical substituent, the described chemical material includes the unsubstituted group and that group for example, substituted with silicon atoms or donor atoms such as nonperoxidic oxygen (e.g., in the chain (i.e., ether) as well as carbonyl groups or other conventional substituents), nitrogen or sulfur. Where the term “moiety” is used to describe a chemical compound or substituent, only an unsubstituted chemical material is intended to be included. For example, the phrase “alkyl group” is intended to include not only pure open chain saturated hydrocarbon alkyl substituents, such as methyl, ethyl, propyl, t-butyl, and the like, but also alkyl substituents bearing further substituents known in the art, such as hydroxy, alkoxy, alkylsulfonyl, halogen atoms, cyano, nitro, amino, carboxyl, etc. Thus, “alkyl group” includes ether groups, haloalkyls, nitroalkyls, carboxyalkyls, hydroxyalkyls, sulfoalkyls, etc. On the other hand, the phrase “alkyl moiety” is limited to the inclusion of only pure open chain saturated hydrocarbon alkyl substituents, such as methyl, ethyl, propyl, t-butyl, and the like.

Other metal-containing precursor compounds can be used with the compounds of Formula (I) to make various mixed-metal complexes. For example, titanium precursor compounds can be mixed with Group 2 metal-containing precursors of Formula (I) to make high-quality dielectric layers containing Group 2 metal titanates such as MgTiO₃, SrTiO₃, and BaTiO₃. Suitable organo-titanium compounds include, for example, titanium tetraisopropoxide, titanium tetra-n-butoxide, titanium tetra-t-butoxide, titanium tetra-2-ethylhexoxide, tetrakis(2-ethylhexane-1,3-diolato) titanium (i.e., octyleneglycol titanate), titanium diisopropoxide bis(acetylacetonate), titanium diisopropoxide bis(2,2,6,6-tetramethyl-3,5-heptanedionate, titanium bis(ethyl acetacetato)diisopropoxide, bis(ethylacetoacetato) bis(alkanolato)titanium, tetrakis(dimethylamino)titanium, tetrakis(diethylamino)titanium, tetrakis(ethyl methyl amino)titanium, titanium (triethanol aminato)isopropoxide, all available from Sigma-Aldrich Chemical Co., Milwaukee, Wisconsin.

As discussed above, the precursor compounds may be liquids or solids at room temperature (preferably, they are liquids at the vaporization temperature). Typically, they are liquids sufficiently volatile to be employed using known vapor deposition techniques. However, as solids they may also be sufficiently volatile that they can be vaporized or sublimed from the solid state using known vapor deposition techniques.

Various combinations of reaction gases can also be used in the methods of the present invention. The reaction gas can be selected from a wide variety of gases reactive with the precursor compounds described herein, at least at a surface under the conditions of atomic layer adsorption. Examples of suitable reaction gases include oxidizing and reducing gases such as water vapor, oxygen, ozone, hydrogen peroxide, nitrous oxide, ammonia, organic amines, silanes, hydrogen, hydrogen sulfide, hydrogen selenide, hydrogen telluride, and combinations thereof. Water vapor is the preferred reaction gas for the deposition of oxides using the precursor compounds described herein.

The precursor compounds can be vaporized in the presence of an inert carrier gas if desired. Additionally, an inert carrier gas can be used in purging steps, as described below. The inert carrier gas is typically selected from the group consisting of nitrogen, helium, argon, and mixtures thereof. In the context of the present invention, an inert carrier gas is one that is generally unreactive with the complexes described herein and does not interfere with the formation of the desired metal-containing film (i.e., layer).

The deposition process for this invention is a vapor deposition process. Vapor deposition processes are generally favored in the semiconductor industry due to the process capability to quickly provide highly conformal layers even within deep contacts and other openings. Chemical vapor deposition (CVD) and atomic layer deposition (ALD) are two vapor deposition processes often employed to form thin, continuous, uniform, metal-containing (preferably dielectric) layers onto semiconductor substrates. Using either vapor deposition process, typically one or more precursor compounds are vaporized in a deposition chamber and optionally combined with one or more reaction gases to form a metal-containing layer onto a substrate. It will be readily apparent to one skilled in the art that the vapor deposition process may be enhanced by employing various related techniques such as plasma assistance, photo assistance, laser assistance, as well as other techniques.

Preferably, the vapor deposition process employed in the methods of the present invention is a multi-cycle ALD process. Such a process is advantageous (particularly over a CVD process) in that it provides for optimum control of atomic-level thickness and uniformity to the deposited layer (e.g., dielectric layer) and to expose the metal precursor compounds to lower volatilization and reaction temperatures to minimize degradation. Typically, in an ALD process, each reactant is pulsed sequentially onto a suitable substrate, typically at deposition temperatures of about 25° C. to about 400° C. (preferably about 100° C. to about 300° C.), which is generally lower than presently used in CVD processes. Under such conditions the film growth is typically self-limiting (i.e., when the reactive sites on a surface are used up in an ALD process, the deposition generally stops), insuring not only excellent conformality but also good large area uniformity plus simple and accurate thickness control. Due to alternate dosing of the precursor compounds and/or reaction gases, detrimental vapor-phase reactions are inherently eliminated, in contrast to the CVD process that is carried out by continuous coreaction of the precursors and/or reaction gases. (See Vehkamaki et al, “Growth of SrTiO₃ and BaTiO₃ Thin Films by Atomic Layer Deposition,” Electrochemical and Solid-State Letters, 2 (10): 504-506 (1999)).

A typical ALD process includes exposing an initial substrate to a first chemical species (e.g., a Group 2 metal precursor compound) to accomplish chemisorption of the species onto the substrate. Theoretically, the chemisorption forms a monolayer that is uniformly one atom or molecule thick on the entire exposed initial substrate. In other words, a saturated monolayer. Practically, chemisorption might not occur on all portions of the substrate. Nevertheless, such an imperfect monolayer is still a monolayer in the context of the present invention. In many applications, merely a substantially saturated monolayer may be suitable. A substantially saturated monolayer is one that will still yield a deposited layer exhibiting the quality and/or properties desired for such layer.

The first species is purged from over the substrate and a second chemical species (e.g., a different compound of Formula (I), a metal-containing compound of a formula other than that of Formula (I), or a reaction gas) is provided to react with the first monolayer of the first species. The second species is then purged and the steps are repeated with exposure of the second species monolayer to the first species. In some cases, the two monolayers may be of the same species. As an option, the second species can react with the first species, but not chemisorb additional material thereto. That is, the second species can cleave some portion of the chemisorbed first species, altering such monolayer without forming another monolayer thereon. Also, a third species or more may be successively chemisorbed (or reacted) and purged just as described for the first and second species.

Purging may involve a variety of techniques including, but not limited to, contacting the substrate and/or -monolayer with a carrier gas and/or lowering pressure to below the deposition pressure to reduce the concentration of a species contacting the substrate and/or chemisorbed species. Examples of carrier gases include N₂, Ar, He, etc. Purging may instead include contacting the substrate and/or monolayer with any substance that allows chemisorption by-products to desorb and reduces the concentration of a contacting species preparatory to introducing another species. The contacting species may be reduced to some suitable concentration or partial pressure known to those skilled in the art based on the specifications for the product of a particular deposition process.

ALD is often described as a self-limiting process, in that a finite number of sites exist on a substrate to which the first species may form chemical bonds. The second species might only bond to the first species and thus may also be self-limiting. Once all of the finite number of sites on a substrate are bonded with a first species, the first species will often not bond to other of the first species already bonded with the substrate. However, process conditions can be varied in ALD to promote such bonding and render ALD not self-limiting. Accordingly, ALD may also encompass a species forming other than one monolayer at a time by stacking of a species, forming a layer more than one atom or molecule thick.

The described method indicates the “substantial absence” of the second precursor (i.e., second species) during chemisorption of the first precursor since insignificant amounts of the second precursor might be present. According to the knowledge and the preferences of those with ordinary skill in the art, a determination can be made as to the tolerable amount of second precursor and process conditions selected to achieve the substantial absence of the second precursor.

Thus, during the ALD process, numerous consecutive deposition cycles are conducted in the deposition chamber, each cycle depositing a very thin metal-containing layer (usually less than one monolayer such that the growth rate on average is from about 0.2 to about 3.0 Angstroms per cycle), until a layer of the desired thickness is built up on the substrate of interest. The layer deposition is accomplished by alternately introducing (i.e., by pulsing) Group 2 metal precursor compound(s) and reaction compound(s) into the deposition chamber containing a semiconductor substrate, chemisorbing the precursor compound(s) as a monolayer onto the substrate surfaces, and then reacting the chemisorbed precursor compound(s) with the other co-reactive precursor compound(s). The pulse duration of precursor compound(s) and inert carrier gas(es) is sufficient to saturate the substrate surface. Typically, the pulse duration is from about 0.1 to about 5 seconds, preferably from about 0.2 to about 1 second.

In comparison to the predominantly thermally driven CVD, ALD is predominantly chemically driven. Accordingly, ALD is often conducted at much lower temperatures than CVD. During the ALD process, the substrate temperature is maintained at a temperature sufficiently low to maintain intact bonds between the chemisorbed precursor compound(s) and the underlying substrate surface and to prevent decomposition of the precursor compound(s). The temperature is also sufficiently high to avoid condensation of the precursor compound(s). Typically the substrate temperature is kept within the range of about 25° C. to about 400° C. (preferably about 150° C. to about 300° C.), which is generally lower than presently used in CVD processes. Thus, the first species or precursor compound is chemisorbed at this temperature. Surface reaction of the second species or precursor compound can occur at substantially the same temperature as chemisorption of the first precursor or, less preferably, at a substantially different temperature. Clearly, some small variation in temperature, as judged by those of ordinary skill, can occur but still be a substantially same temperature by providing a reaction rate statistically the same as would occur at the temperature of the first precursor chemisorption. Chemisorption and subsequent reactions could instead occur at exactly the same temperature.

For a typical ALD process, the pressure inside the deposition chamber is kept at about 10-4 torr to about 1 torr, preferably about 10-4 torr to about 0.1 torr. Typically, the deposition chamber is purged with an inert carrier gas after the vaporized precursor compound(s) have been introduced into the chamber and/or reacted for each cycle. The inert carrier gas(es) can also be introduced with the vaporized precursor compound(s) during each cycle.

The reactivity of a precursor compound can significantly influence the process parameters in ALD. Under typical CVD process conditions, a highly reactive compound may react in the gas phase generating particulates, depositing prematurely on undesired surfaces, producing poor films, and/or yielding poor step coverage or otherwise yielding non-uniform deposition. For at least such reason, a highly reactive compound might be considered not suitable for CVD. However, some compounds not suitable for CVD are superior ALD precursors. For example, if the first precursor is gas phase reactive with the second precursor, such a combination of compounds might not be suitable for CVD, although they could be used in ALD. In the CVD context, concern might also exist regarding sticking coefficients and surface mobility, as known to those skilled in the art, when using highly gas-phase reactive precursors, however, little or no such concern would exist in the ALD context.

As stated above, the use of the complexes and methods of forming films of the present invention are beneficial for a wide variety of thin film applications in semiconductor structures, particularly those using high dielectric materials or ferroelectric materials. For example, such applications include capacitors such as planar cells, trench cells (e.g., double sidewall trench capacitors), stacked cells (e.g., crown, V-cell, delta cell, multi-fingered, or cylindrical container stacked capacitors), as well as field effect transistor devices.

The following example illustrates the preparation of the Group 2 metal-containing complexes disclosed herein as well as their use as precursors in metal-containing film deposition processes.

### Examples

The following example illustrates the preparation of the Group 2 organometallic precursors.

### Synthesis (General)

One equivalent of the Magnesium Cyclopentadienyl complex was dissolved in anhydrous hexane and reacted with one equivalent of diamine reagents according to the following reaction scheme:

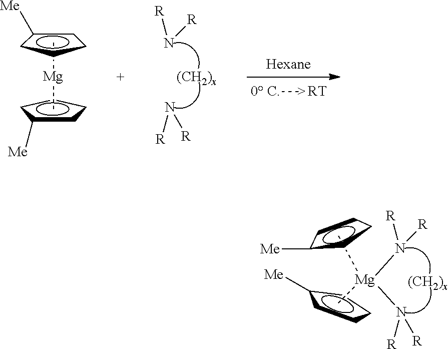

Pure Mg(MeCp)₂ (diamine) complexes were obtained by sublimation reduced pressure. According to 1HNMR, 13C NMR, and X-ray crystallography, the complexes below are monomeric (Mg(η⁵-Cp)(η²-Cp)(NRR(CH₂)ₓNRR):

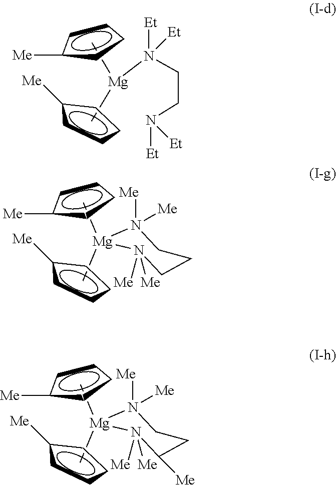

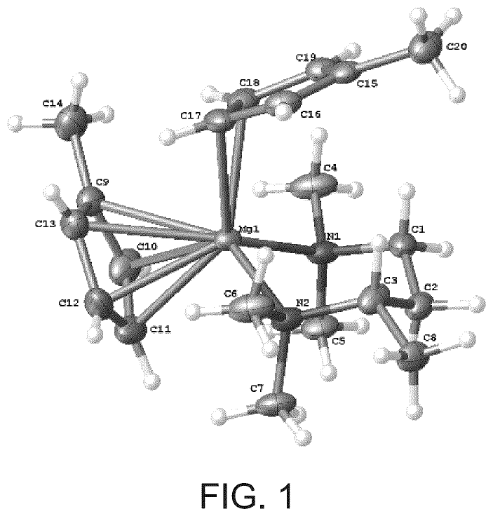

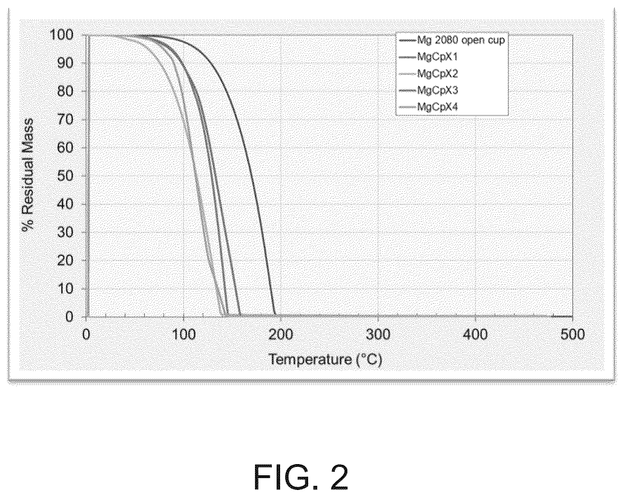

Approximately 0.5 g of pure complexes were removed from the inert conditions (glove box) and investigated the reaction under air. All complexes changed color from white to brown, indicating the reaction with moisture and oxygen, but none was pyrophoric. TGA analyzed the volatilities and thermal stabilities. According to Thermograms, all of these complexes are volatile. Compared to the Mg(MeCP)₂ complex, these novel complexes are more volatile. The X-ray crystal structure of complex (I-h) (N1,N1,N3,N3-Tetramethyl-1,3-butanediamine) is presented in FIG. 1, and TGA graphs are in FIG. 2.

Referring to FIG. 1, the Mg(II) ion has coordination number 9. One of the MeCp ligands is η5-coordinated. Another MeCp ligand is η2-coordinated. The coordinated bond is elongated and shows signs of σ-distortion (hydrogen atoms at C17 and C18 deviate from TT-plane; their positions were refined independently). The chelate ligand has a chair conformation with “chiral” Me-group C8 disordered between C1 and C3 positions with non-equal populations—40 and 60%). Complex 4 can also be shown as:

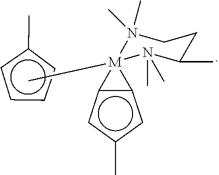

Synthesis Route for (nBu)Mg(MeCp)(TMEDA):

### (TMEDA: Tetramethylethyelenediamine)

The reactions were conducted under inert atmospheric conditions using a glove box or Schlenk line. Sodium hydride, NaH, was charged into a 250 mL 3-neck flask, and anhydrous tetrahydrofuran was added to make a suspension. Methylcyclopentadiene (MeCpH) was added slowly to the NaH suspension, while maintaining the temperature below 35° C. The resulting NaMeCp reaction mixture was stirred overnight. A THF solution of Mg(nBu)Cl was added to a clean 500 mL 3-neck flask. The previously prepared NaMeCp was then added slowly. The mixture was stirred for 18 hours. Tetramethylethylenediammine (TMEDA) ligand was then added to the reaction flask; the THF was removed under vacuum; the resulting off-white solid was extracted with anhydrous hexane. Hexane was removed to produce a yellow-colored solid and 1H NMR confirmed the structure of the compound.

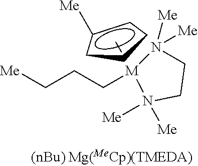

1H NMR data (400 MHZ, C6D6, 25° C.): δ=6.26 (s, 2H, CpH), 6.00 (s, 2H, CpH), 2.64 (s, 3H, CpCH3), 1.84-1.73- (m, 4H, CH2CH2CH2CH3), 1.68 (m, 10H, TMEDA-H), 1.33-1.30 (t, 3H, CH2-CH2-CH2-CH3), (−)0.60-(−)0.63 (t, 2H, CH2-CH2-CH2-CH3)

Synthesis Route for Mg(^{Et}Cp)₂(TEEDA) and Mg(^{MeCp})₂(TEEDA):

### (TEEDA: Tetraethylethyelenediamine)

The reactions were conducted under inert air conditions using a glove box or Schlenk line. To a 500 mL 3-neck flask, respective Pure Mg(^{R}Cp)₂ (R=Et or Me) was added and diluted with 100 ml of hexane. TEEDA ligand was charged into a syringe and added to the respective reaction flask while maintaining the temperature below 35° C. The reaction mixture was allowed to come to room temperature and stirred overnight. Hexane was removed using vacuum and white solid was isolated. Each white solid was subjected to vacuum sublimation according to the following conditions.
Mg(^{Et}Cp)₂(TEEDA): 55° C. at 0.5 Torr
Mg(^{Me}Cp)₂(TEEDA): 80° C. at 0.5 Torr

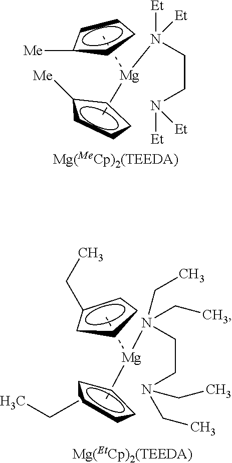

Synthesis Route for (nBu)₂Mg(TEEDA): (TEEDA: Tetraethylethyelenediamine)

The reactions were conducted under inert air conditions using a glove box or Schlenk line. To a 500 mL 3-neck flask, 50 ml of 1M di-n-butyl magnesium was added. 1 mol equivalent TEEDA ligand was charged into a syringe and added to Mg(n-Bu) 2 solution while maintaining the temperature below 35° C. The reaction mixture was allowed to come to room temperature and stirred overnight. Hexane was removed using vacuum and viscous liquid was isolated, material further purified by vacuum distillation.

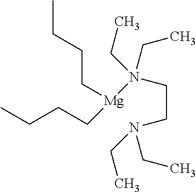

1H NMR data (400 MHZ, C6D6, 25° C.), δ −0.23 (4H, triplet, Mg—CH2-CH2-CH2-CH3), δ 1.25 (6H, triplet, Mg—CH2-CH2-CH2-CH3), δ 2.07 (4H, m, Mg—CH2-CH2-CH2-CH3), δ 2.14 (4H, m, Mg—CH2-CH2-CH2-CH3), δ 0.65 (12H, triplet, N—CH2-CH3), δ 1.182 (broad singlet, N—(CH2)2-N), δ 1.182.

### Synthesis Route for (MeCp)2Mg(DEMEA):

The reactions were conducted under inert air conditions using a glove box or Schlenk line. To a 250 mL 3-neck flask, Pure Mg(MeCp)₂ was added and diluted with 100 mL of hexane. N, N-Diethyl-2-methoxyethanamine ligand was charged into a syringe and added to the respective reaction flask while maintaining the temperature below 35° C. The reaction mixture was allowed to come to room temperature and stirred overnight. Hexane was removed using vacuum and white solid was isolated, resulting solid was subjected to vacuum sublimation at 45° C. and 0.5 torr to obtain pure product.

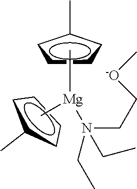

1H NMR data (400 MHZ, C₆D6, 25° C.), δ 0.06 (4H, triplet), δ 0.6 (6H), δ 1.91 (2H), δ 2.19 (4H), δ 2.41 (6H), δ 2.51 (2H), δ 2.86 (3H).

Sublimation, melting points, and % residues after TG analysis of compounds exemplified are presented in Table 1.

TABLE 1
Thermal Characterization of Exemplary Compounds

| | Sublimation | Melting | |
|---|---|---|---|
| | at 0.5 | Point | |
| Complex | Torr/° C. | (° C.) | Residue |
| 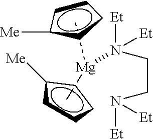 | 80 (white solid) | 67 | <0.5% |
| MgCpX2 | | | |
| 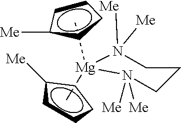 | 60 (white solid) | 120 | <0.1% |
| MgCpX3 | | | |
| 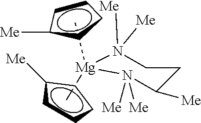 | 60 (white solid) | 104 | <0.2% |
| MgCpX4 | | | |
| 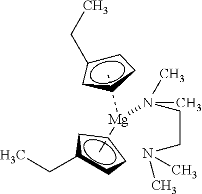 | 60 | 72 | <0.2% |
| 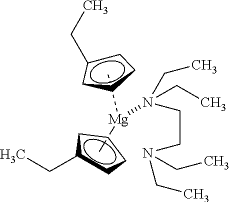 | 55 | 57 | <0.2% |

Synthesis Route for Ba(ipr₃Cp)₂(TEEDA): (TEEDA: Tetraethylethyelenediamine)

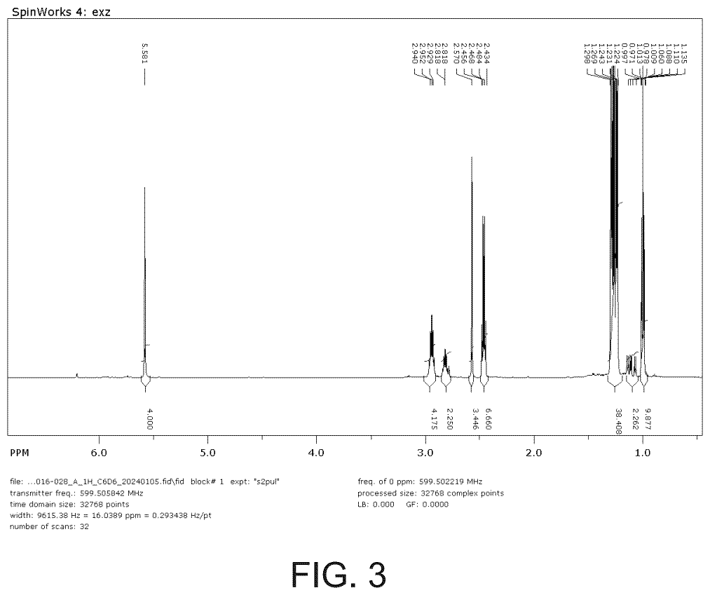

The reactions were conducted under inert air conditions using a glove box or Schlenk line. To a 250 mL 3-neck flask, respective 5 g Pure Ba(iPr₃Cp)₂ was added and diluted with 80 mL of hexane. Exactly 2 mL of (1 equivalence) of TEEDA ligand was added slowly and refluxed for 4 h. The reaction mixture was stirred overnight. Hexane was removed using vacuum resulting yellow oil (5.8 g, 97%) and 1H NMR confirmed the structure of the compound as presented in FIG. 3.

¹H NMR data (benzene-d₆, 23° C., δ) 5.58 (s, 4H, iPr₃CpH), 2.94-2.92 (m, 4H, (CH₃CHCH₃)₃Cp), 2.78-2.83 (m, 2H, (CH₃CHCH₃)₃Cp), 2.57 (s, 4H, Et₂NCH₂CH₂NEt₂) 2.45-2.43 (q, 8H, (CH₃CH₂)₂NCH₂CH₂N(CH₂CH₃)₂), 1.29-1.22 (m, 36H, (CH₃CHCH₃)₃Cp, 1.01-0.97 (t, 9H, (CH₃CH₂)₂NCH₂CH₂N(CH₂CH₃)₂).

Synthesis Route for Ba(ipr₃Cp)₂(Me₂NCH₂CH₂CH₂NMe₂):

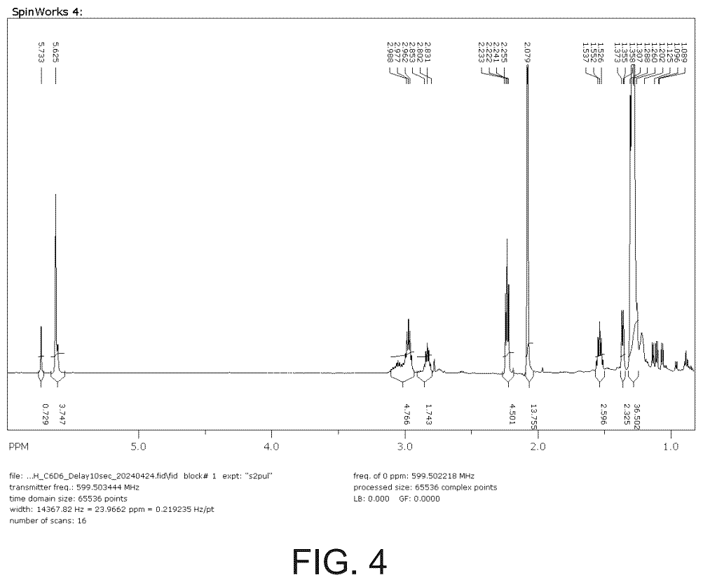

The reactions were conducted under inert air conditions using a glove box or Schlenk line. To a 250 mL 3-neck flask, respective 5 g Pure Ba(iPr₃Cp)₂ was added and diluted with 80 mL of hexane. Exactly 2 mL of (1 equivalence) of N,N,N′,N′-Tetramethyl-1,3-propanediamine ligand was added slowly and refluxed for 4 h. The reaction mixture was stirred overnight. Red oily material was isolated by removing hexane (5.5 g, 93%). and ¹H NMR confirmed the structure of the compound as presented in FIG. 4.

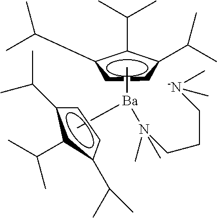

1H NMR (benzene-d₆, 23° C., δ) 5.73-5.62 (m, 4H, iPr₃CpH), 2.98-2.83 (m, 6H, (CH₃CHCH₃)₃Cp), 2.25-2.23 (m, 4H, (Me₂NCH₂CH₂CH₂NMe₂)), 2.08 (s, 12H, Me₂NCH₂CH₂CH₂NMe₂) 1.52-1.53 (m, 2H, (Me₂NCH₂CH₂CH₂NMe₂)), 1.30-1.27 (m, 36H, (CH₃CHCH₃)₃Cp.

The foregoing examples and description of the preferred embodiments should be taken as illustrating, rather than as limiting the present invention as defined by the claims. As will be readily appreciated, numerous variations and combinations of the features set forth above can be utilized without departing from the present invention as set forth in the claims. Such variations are not regarded as a departure from the spirit and scope of the invention, and all such variations are intended to be included within the scope of the following claims.

We claim:

1. A composition comprising an organometallic complex of Formula I: 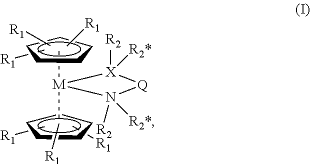
wherein,
M is selected from the group consisting of Mg, Ca, Ba, and Sr;
X is selected from the group consisting of N and O, provided that when X is O, the R₂* is absent;
Q is either the ligand 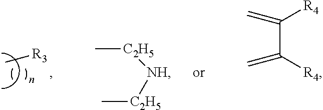
provided that when Q is 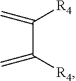
each R₂* is not present;
each R₁ is independently hydrogen or a C₁-C₄ linear or branched alkyl;
each R₂ and R₂* is independently selected from the group consisting of hydrogen, methyl, ethyl, n-propyl, iso-propyl, n-butyl, iso-butyl, and tert-butyl, wherein at least one R₁ may be connected to an R₂ to form a C₂-C₅ alkylene bridge;
R₃ is selected from the group consisting of hydrogen or a C₁-C₄ linear or branched alkyl;
each R₄ is independently hydrogen or a C₁-C₄ linear or branched alkyl; and
n is 0, 2, 3, 4 or 5,
wherein when Q is 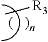
and n is 0, then at least one N forms a C₂-C₅ alkylene bridge with an R₁ via either R₂ or R₂*, and the other N either forms a C₂-C₅ alkylene bridge with another R₁ via either R₂ or R₂*, or is 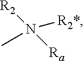
where Rₐ is a C₁-C₄ linear or branched alkyl, and
provided that, when n is 2, not all of R₁ and R₂ are methyl or hydrogen when R₃ is hydrogen.

2. The composition of claim 1 wherein the compound of Formula I is a monomer.

3. The composition of claim 1 wherein the compound of Formula I has a melting point in the range of from 10 to 80° C.

4. The composition of claim 1 wherein M is Mg.

5. The composition of claim 1 wherein M is Ca.

6. The composition of claim 1 wherein M is Ba.

7. The composition of claim 1 wherein M is Sr.

8. The composition of claim 1 wherein Q is

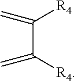

9. The composition of claim 1 wherein Q is 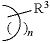
and n is not 0.

10. The composition of claim 9 wherein each R₁ is methyl, each R₂ is ethyl, and R₃ is hydrogen.

11. The composition of claim 9 wherein each R₁ is ethyl, each R₂ is ethyl, and R₃ is hydrogen.

12. The composition of claim 1 wherein Q is 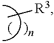
n is 3, each R₁ is methyl, each R₂ is ethyl, and R₃ is ethyl.

13. The composition of claim 1 wherein Q is 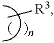
n is 5, each R₁ is methyl or ethyl, each R₂ is methyl, and R₃ is hydrogen.

14. The composition of claim 1 wherein the composition further comprises an organic solvent.

15. The composition of claim 14 wherein the organic solvent is selected from the group consisting of an aliphatic ether, a cyclic ether, an aromatic hydrocarbon, an aliphatic hydrocarbon, an alkyl silane, and mixtures thereof.

16. The composition of claim 14 wherein the organic solvent is selected from the group consisting of THE, toluene, hexanes, ether, and mixtures thereof.

17. The composition of claim 1 wherein each R₁ is methyl, each R₂ is ethyl, and R₃ is ethyl.

18. The composition of claim 1 wherein the organometallic complex is selected from

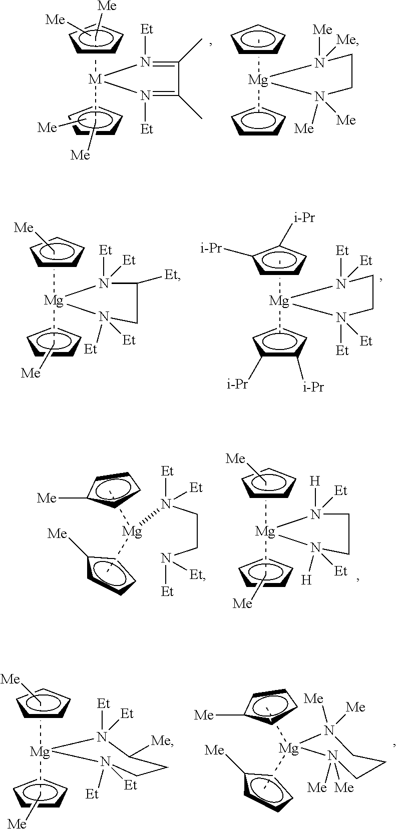

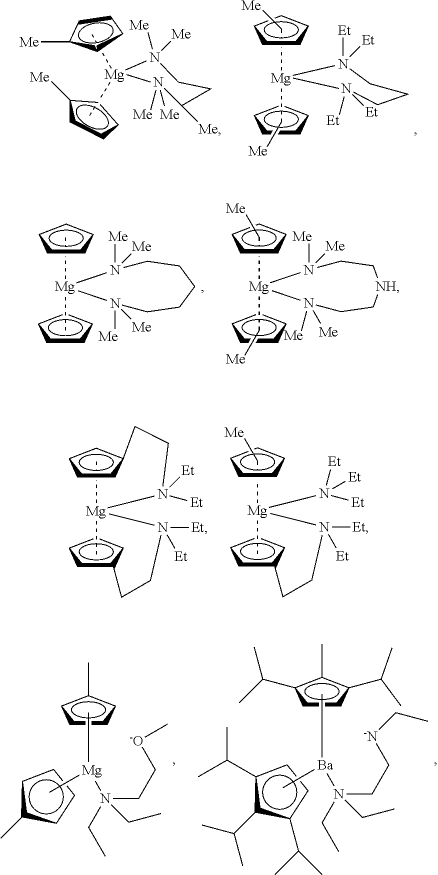

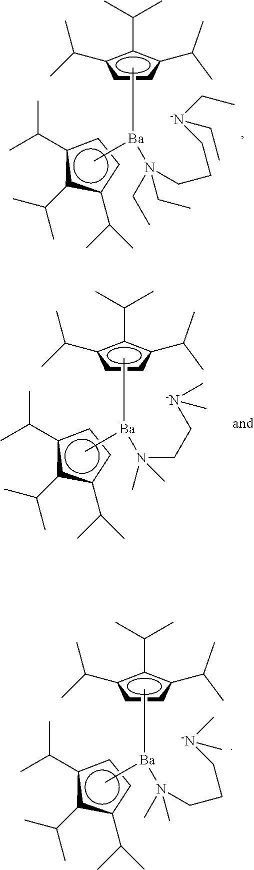

19. A composition comprising an organometallic complex of Formula II: 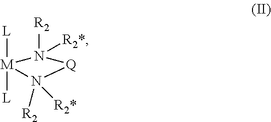
wherein,
M is selected from the group consisting of Mg, Ca, Ba, and Sr;
L is selected from the group consisting of 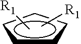
and a C₁-C₆ linear or branched alkyl;
Q is either the ligand 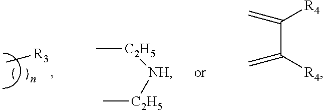
provided that when Q is 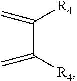
each R₂* is not present;
each R₁ is independently hydrogen or a C₁-C₄ linear or branched alkyl;
each R₂ and R₂* is independently selected from the group consisting of hydrogen, methyl, ethyl, n-propyl, iso-propyl, n-butyl, tert-butyl, and iso-butyl, wherein at least one R₁ may be connected to an R₂ to form a C₂-C₅ alkylene bridge;
R₃ is selected from the group consisting of hydrogen or a C₁-C₄ linear or branched alkyl;
each R₄ is independently hydrogen or a C₁-C₄ linear or branched alkyl; and
n is 0, 2, 3, 4 or 5,
wherein when Q is 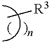
and n is 0, then at least one N forms a C₂-C₅ alkylene bridge with an R₁ via either R₂ or R₂*, and the other N either forms a C₂-C₅ alkylene bridge with another R₁ via either R₂ or R₂*, or is 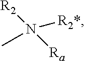
wherein Rₐ is a C₁-C₄ linear or branched alkyl, and provided that, when n is 2, not all of R₁ and R₂ are methyl or hydrogen when R₃ is hydrogen.

20. The composition of claim 19 wherein the organometallic complex is selected from 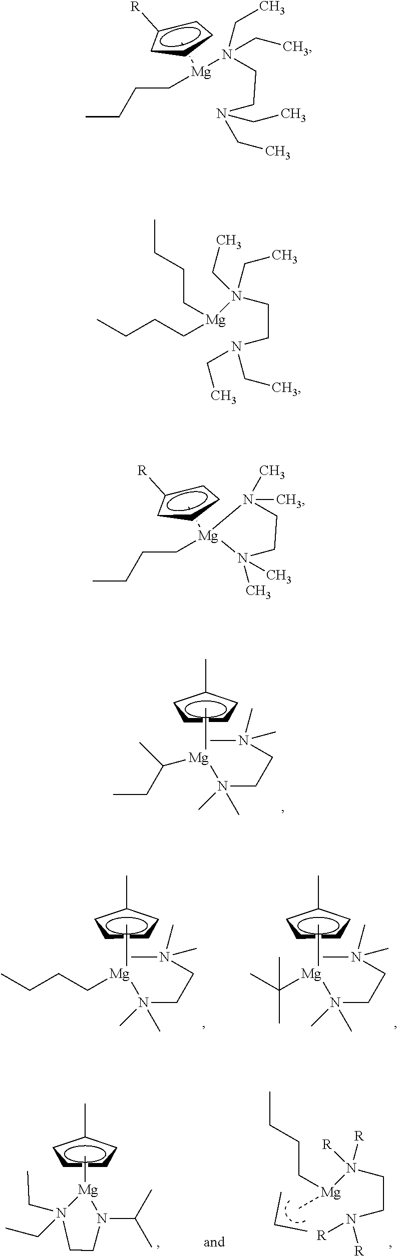
wherein R is independently methyl or ethyl.

21. A method of forming a layer on a substrate, wherein the method comprises the steps of: providing a substrate; providing a vapor including one or more Group 2 metal precursor compounds of Formula (I); and forming a metal-containing layer on a surface of the substrate using an atomic layer deposition process that includes a plurality of deposition cycles.

22. The method of claim 21 wherein the substrate is a semiconductor substrate.

23. The method of claim 21 wherein M is Mg.

24. A method of forming a layer on a substrate, wherein the method comprises the steps of: providing a substrate; providing a vapor including one or more Group 2 metal precursor compounds of Formula (I); providing one or more reaction gases; and directing the vapor including the one or more Group 2 metal precursor compounds and the one or more reaction gases to the substrate to form a metal-containing layer on a surface of the substrate using a chemical vapor deposition process.

25. The method of claim 24 wherein the substrate is a semiconductor substrate.

26. The method of claim 24 wherein the one or more reaction gases is water vapor.

27. The method of claim 24 wherein Mis Mg.

28. A composition comprising an organometallic complex of Formula III: 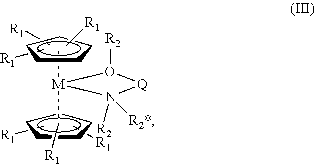
wherein,
M is selected from the group consisting of Mg, Ca, Ba, and Sr;
Q is either the ligand 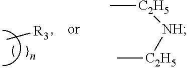
each R₁ is independently hydrogen or a C₁-C₄ linear or branched alkyl;
each R₂ and R₂* is independently selected from the group consisting of hydrogen, methyl, ethyl, n-propyl, iso-propyl, n-butyl, iso-butyl, and tert-butyl, wherein at least one R₁ may be connected to an R₂ to form a C₂-C₅ alkylene bridge;
R₃ is selected from the group consisting of hydrogen or a C₁-C₄ linear or branched alkyl;
each R₄ is independently hydrogen or a C₁-C₄ linear or branched alkyl; and
n is 0, 2, 3, 4 or 5,
wherein when Q is 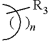
and n is 0, then at least one N forms a C₂-C₅ alkylene bridge with an R₁ via either R₂ or R₂*, and the other N either forms a C₂-C₅ alkylene bridge with another R₁ via either R₂ or R₂*, or is 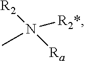
wherein Rₐ is a C₁-C₄ linear or branched alkyl, and
provided that, when n is 2, not all of R₁ and R₂ are methyl or hydrogen when R₃ is hydrogen.

29. The composition of claim 28 wherein M is Mg.

30. The composition of claim 28 wherein the organometallic complex is [chemical structure]
